(19) United States
(12) Patent Application Publication
(10) Pub. No.: US 2020/0098924 A1
(43) Pub. Date: Mar. 26, 2020

(54) TRANSISTOR SUBSTRATE, METHOD OF MANUFACTURING THE SAME, AND DISPLAY DEVICE INCLUDING THE SAME

(71) Applicant: Samsung Display Co., Ltd., Yongin-Si (KR)

(72) Inventors: Tae Sang KIM, Seoul (KR); Joon Seok PARK, Yongin-si (KR); Kwang Suk KIM, Suwon-si (KR); Yeon Keon MOON, Hwaseong-si (KR); Geunchul PARK, Suwon-si (KR); Jun Hyung LIM, Seoul (KR); Kyung Jin JEON, Incheon (KR)

(21) Appl. No.: 16/563,699

(22) Filed: Sep. 6, 2019

(30) Foreign Application Priority Data
Sep. 20, 2018 (KR) 10-2018-0113295

(51) Int. Cl. H01L 29/786; H01L 27/12; H01L 21/467; H01L 29/66

(52) U.S. Cl. CPC H01L 29/7869; H01L 27/1225; H01L 27/124; H01L 27/127; H01L 27/3262; H01L 21/467; H01L 29/66969; H01L 29/78618; H01L 27/1288

(57) ABSTRACT

A transistor substrate may include: a substrate; an active pattern formed on the substrate, the active pattern including an oxide semiconductor that contains tin (Sn), and the active pattern including a source region, a drain region, and a channel region that is formed between the source region and the drain region; a source protective pattern formed on the source region; a drain protective pattern formed on the drain region; a gate electrode overlapping at least a portion of the channel region; an insulation interlayer covering the source protective pattern and the drain protective pattern; a source electrode formed on the insulation interlayer, the source electrode being in contact with the source protective pattern through a source contact hole that is formed in the insulation interlayer; and a drain electrode formed on the insulation interlayer, the drain electrode being in contact with the drain protective pattern through a drain contact hole that is formed in the insulation interlayer.

### CROSS-REFERENCE TO RELATED APPLICATION(S)

This application claims priority under 35 USC § 119 to Korean Patent Application No. 10-2018-0113295, filed on Sep. 20, 2018 in the Korean Intellectual Property Office (KIPO), the disclosure of which is incorporated by reference herein in its entirety.

### BACKGROUND

### 1. Field

Embodiments of the present disclosure relate to a display device. More particularly, embodiments relate to a transistor substrate, a method of manufacturing the transistor substrate, and a display device including the transistor substrate.

### 2. Description of the Related Art

A transistor is used in various electronic devices such as a display device. For example, the transistor may be used as an element of a pixel circuit in a display device such as a liquid crystal display device, an organic light emitting display device, etc.

The transistor may include a gate electrode, a source electrode, a drain electrode, and an active layer that is electrically connected to the source electrode and the drain electrode. The active layer is an important element in determining characteristics of the transistor.

The active layer may include silicon (Si). The silicon may be categorized into amorphous silicon and polycrystalline silicon based on a crystallization type. The amorphous silicon has a simple manufacturing process but has low charge mobility such that there is a limit for manufacturing a high performance transistor. On the other hand, the polycrystalline silicon has high charge mobility but requires a process of crystallizing the silicon that would in turn increase the manufacturing cost and complicate the manufacturing process.

To complement the amorphous silicon and the polycrystalline silicon, studies on a transistor that includes an oxide semiconductor with a higher on/off ratio and higher carrier mobility than the amorphous silicon, and a lower cost and higher uniformity than polycrystalline silicon, have progressed. However, such an oxide semiconductor may be damaged by an etching gas in a process of etching adjacent insulation layers.

### SUMMARY

Embodiments of the present disclosure provide a transistor substrate in which an active pattern may not be damaged and a display device including the transistor substrate.

Embodiments provide a method of manufacturing a transistor substrate for preventing a damage to an active pattern.

A transistor substrate according to embodiments may include: a substrate; an active pattern formed on the substrate; the active pattern including an oxide semiconductor that contains tin (Sn), and the active pattern including a source region, a drain region, and a channel region that is formed between the source region and the drain region; a source protective pattern formed on the source region; a drain protective pattern formed on the drain region; a gate electrode overlapping at least a portion of the channel region; an insulation interlayer covering the source protective pattern and the drain protective pattern; a source electrode formed on the insulation interlayer, the source electrode being in contact with the source protective pattern through a source contact hole that is formed in the insulation interlayer; and a drain electrode formed on the insulation interlayer, the drain electrode being in contact with the drain protective pattern through a drain contact hole that is formed in the insulation interlayer.

In an embodiment, each of the source protective pattern and the drain protective pattern may include an oxide semiconductor that does not contain tin (Sn).

In an embodiment, a width of the source protective pattern and a width of the drain protective pattern may be greater than a width of the source contact hole and a width of the drain contact hole, respectively.

In an embodiment, a width of the source protective pattern and a width of the drain protective pattern may be less than a width of the source region and a width of the drain region, respectively.

In an embodiment, the source electrode and the drain electrode may not be in contact with the source region and the drain region, respectively.

In an embodiment, the transistor substrate may further include a gate insulation layer formed between the channel region and the gate electrode, the gate insulation layer overlapping at least a portion of the channel region.

In an embodiment, the transistor substrate may further include: a buffer layer formed between the substrate and the active pattern; and a metal layer formed between the substrate and the buffer layer, the metal layer overlapping at least a portion of the channel region.

In an embodiment, the transistor substrate may further include a connection pattern formed on the insulation interlayer, the connection pattern being in contact with the metal layer through a metal layer contact hole formed in the buffer layer and the insulation interlayer.

In an embodiment, the metal layer may be electrically connected to the gate electrode or the source electrode through the connection pattern.

A method of manufacturing a transistor substrate according to embodiments may include: forming an active pattern on a substrate, the active pattern including an oxide semiconductor that contains tin (Sn); forming a source protective pattern and a drain protective pattern on opposite ends of the active pattern; forming a gate electrode on a center portion of the active pattern; forming an insulation interlayer covering the source protective pattern and the drain protective pattern; forming a source contract hole and a drain contact hole respectively exposing at least a portion of an upper surface of the source protective pattern and the drain protective pattern in the insulation interlayer; and forming a source electrode and a drain electrode on the insulation interlayer by respectively filling the source contact hole and the drain contact hole.

In an embodiment, forming the active pattern, and forming the source protective pattern and the drain protective pattern may include: forming an oxide semiconductor layer on the substrate, the oxide semiconductor layer including a first oxide semiconductor layer that contains tin and a second oxide semiconductor layer that is formed on the first semiconductor layer and does not contain tin; etching a first portion of the oxide semiconductor layer using a first etchant to form the active pattern; and etching a second portion of the second oxide semiconductor layer using a second etchant to form the source protective pattern and the drain protective pattern.

In an embodiment, the first etchant may include hydrogen fluoride (HF).

In an embodiment, the second etchant may include at least one of phosphoric acid (H₃PO₄), nitric acid (HNO₃), and acetic acid (CH₃COOH).

In an embodiment, forming the active pattern, and forming the source protective pattern and the drain protective pattern may further include: forming a photoresist pattern exposing the first portion of the oxide semiconductor layer on the oxide semiconductor layer after forming the oxide semiconductor layer and before etching the first portion of the oxide semiconductor layer; ashing the photoresist pattern to expose the second portion of the second oxide semiconductor layer after etching the first portion of the oxide semiconductor layer and before etching the second portion of the second oxide semiconductor layer; and stripping the photoresist pattern after etching the second portion of the second oxide semiconductor layer.

In an embodiment, forming the active pattern, and forming the source protective pattern and the drain protective pattern may further include, after forming the oxide semiconductor layer and before forming the photoresist pattern, forming a photoresist layer on the oxide semiconductor layer; and exposing the photoresist layer using a halftone mask.

In an embodiment, the source contact hole and the drain contact hole may be formed by an etching gas including fluorine (F).

In an embodiment, the method may further include: forming a metal layer on the substrate and forming a buffer layer on the metal layer before forming the active pattern;

forming a metal layer contact hole exposing at least a portion of an upper surface of the metal layer in the buffer layer and the insulation interlayer; and forming a connection pattern on the insulation interlayer by filling the metal layer contact hole.

In an embodiment, the metal layer contact hole may be simultaneously formed with the source contact hole and the drain contact hole, and the connection pattern may be simultaneously formed with the source electrode and the drain electrode.

A display device according to embodiments may include a substrate, an active pattern formed on the substrate, the active pattern including an oxide semiconductor that contains tin (Sn), and the active pattern including a source region, a drain region, and a channel region that is formed between the source region and the drain region, a source protective pattern formed on the source region, a drain protective pattern formed on the drain region, a gate electrode overlapping at least a portion of the channel region, an insulation interlayer covering the source protective pattern and the drain protective pattern, a source electrode formed on the insulation interlayer, the source electrode being in contact with the source protective pattern through a source contact hole that is formed in the insulation interlayer, a drain electrode formed on the insulation interlayer, the drain electrode being in contact with the drain protective pattern through a drain contact hole that is formed in the insulation interlayer, a first electrode electrically connected to the source electrode or the drain electrode, a second electrode formed opposite to the first electrode, and an emission layer formed between the first electrode and the second electrode.

In an embodiment, each of the source protective pattern and the drain protective pattern may include an oxide semiconductor that does not contain tin.

In the transistor substrate and the display device according to the present embodiments, the source protective pattern and the drain protective pattern that includes the oxide semiconductor that does not contains tin (Sn) may be respectively disposed on the source region and the drain region of the active pattern such that damages of the source region and the drain region of the active pattern by an etching gas including fluoride (F) may be prevented.

In the method of manufacturing the transistor substrate according to the present embodiments, the source protective pattern and the drain protective pattern that includes the oxide semiconductor that does not contains tin (Sn) may be respectively formed on the source region and the drain region of the active pattern such that damages of the source region and the drain region of the active pattern by an etching gas including fluoride (F) may be prevented in a process of forming the source contact hole and the drain contact hole using the etching gas. Further, the active pattern, the source protective pattern, and the drain protective pattern may be formed in a single photolithography process using the halftone mask such that a cost and a time for manufacturing the transistor substrate may be reduced.

### BRIEF DESCRIPTION OF THE DRAWINGS

Illustrative, non-limiting embodiments of the present disclosure will be more clearly understood from the following detailed description taken in conjunction with the accompanying drawings.

FIG. 1 is a cross-sectional view illustrating a transistor substrate according to an embodiment.

FIGS. 2, 3, 4, 5, 6, 7, 8, 9, and 10 are cross-sectional views illustrating a method of manufacturing the transistor substrate in FIG. 1.

FIG. 11 is a cross-sectional view illustrating a transistor substrate according to another embodiment.

FIGS. 12 and 13 are cross-sectional views illustrating a method of manufacturing the transistor substrate in FIG. 11.

FIG. 14 is a cross-sectional view illustrating a display device according to an embodiment.

### DETAILED DESCRIPTION OF THE EMBODIMENTS

Hereinafter, transistor substrates, methods of manufacturing the transistor substrates, and display devices including the transistor substrates in accordance with exemplary embodiments of the present disclosure will be explained in detail with reference to the accompanying drawings.

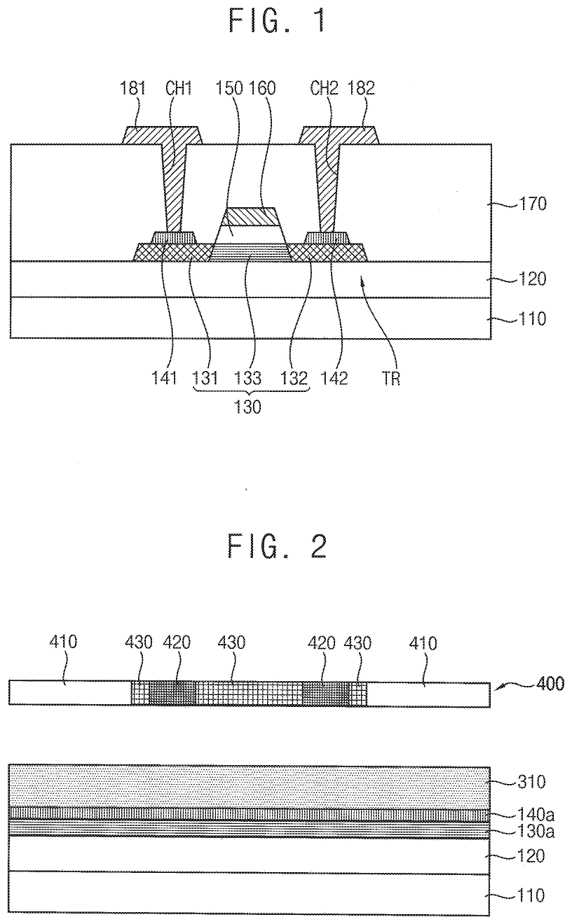

Hereinafter, a transistor substrate according to an embodiment will be described with reference to FIG. 1.

FIG. 1 is a cross-sectional view illustrating a transistor substrate according to an embodiment.

Referring to FIG. 1, a transistor substrate may include a substrate 110 and a transistor TR.

The substrate 110 may be an insulation substrate including glass, quartz, ceramic, plastic, etc.

A buffer layer 120 may be disposed on the substrate 110. The buffer layer 120 may prevent permeation of impurities such as oxygen, moisture, etc. through the substrate 110. The buffer layer 120 may provide a planarized surface on the substrate 110. The buffer layer 120 may include silicon nitride (SiNₓ), silicon oxide (SiOₓ), etc. In an embodiment, the buffer layer 120 may have a stacked structure including a silicon nitride layer and a silicon oxide layer.

The transistor TR may be disposed on the buffer layer 120. The transistor TR may include an active pattern 130, a gate electrode 160, a source electrode 181, and a drain electrode 182.

In an embodiment, the transistor TR may be an n-channel transistor. In another embodiment, the transistor TR may be a p-channel transistor.

The active pattern 130 may be disposed on the buffer layer 120. The active pattern 130 may include a source region 131, a drain region 132, and a channel region 133 disposed therebetween.

The active pattern 130 may include an oxide semiconductor that contains tin (Sn). The active pattern 130 may include a metal oxide including tin (Sn), or a combination of a metal including tin (Sn) and an oxide thereof. For example, the metal oxide may include tin oxide (SnO₂), zinc tin oxide (ZTO), indium zinc tin oxide (IZTO), indium gallium zinc tin oxide (IGZTO), etc.

A source protective pattern 141 may be disposed on the source region 131 of the active pattern 130, and a drain protective pattern 142 may be disposed on the drain region 132 of the active pattern 130. The source protective pattern 141 and the drain protective pattern 142 may be disposed on an upper surface of the source region 131 and an upper surface of the drain region 132, respectively.

Each of the source protective pattern 141 and the drain protective pattern 142 may include an oxide semiconductor that does not contain tin (Sn). Each of the source protective pattern 141 and the drain protective pattern 142 may include a metal oxide that does not include tin (Sn), or a combination of a metal excluding tin (Sn) and an oxide thereof. For example, the metal oxide may include zinc oxide (ZnO), indium oxide (InO), gallium oxide (GaO), indium zinc oxide (IZO), indium gallium oxide (IGO), indium gallium zinc oxide (IGZO), etc.

In an embodiment, a width of the source protective pattern 141 and a width of the drain protective pattern 142 may be less than a width of the source region 131 and a width of the drain region 132, respectively. Accordingly, a portion of the upper surface of the source region 131 may not be covered by the source protective pattern 141, and a portion of the upper surface of the drain region 132 may not be covered by the drain protective pattern 142.

A gate insulation layer 150 may be disposed on the active pattern 130. The gate insulation layer 150 may overlap at least a portion of the channel region 133 in the cross-sectional view. The gate insulation layer 150 may include an insulating material such as silicon oxide (SiOₓ), silicon nitride (SiNₓ), etc. The gate insulation layer 150 may not cover the source region 131, the drain region 132, the source protective pattern 141, and the drain protective pattern 142 such that an insulation interlayer 170 may be in direct contact with the source region 131, the drain region 132, the source protective pattern 141, and the drain protective pattern 142. Therefore, the source region 131, the drain region 132, the source protective pattern 141, and the drain protective pattern 142 may be conductive because hydrogen inflowed from the insulation interlayer 170 may be diffused in the source region 131, the drain region 132, the source protective pattern 141, and the drain protective pattern 142.

The gate electrode 160 may be disposed on the gate insulation layer 150. The gate electrode 160 may overlap at least a portion of the active pattern 130. More specifically, the gate electrode 160 may overlap at least a portion of the channel region 133. The gate electrode 160 may include at least one of copper (Cu), a cooper alloy, aluminum (Al), an aluminum alloy, molybdenum (Mo), and a molybdenum alloy.

The insulation interlayer 170 may be disposed on the gate electrode 160. The insulation interlayer 170 may be disposed on the buffer layer 120 and may cover the active pattern 130, the source protective pattern 141, the drain protective pattern 142, and the gate electrode 160. The insulation interlayer 170 may include an insulating material such as silicon oxide (SiOₓ), silicon nitride (SiNₓ), etc.

A source contact hole CH1 and a drain contact hole CH2 may be formed in the insulation interlayer 170. The source contact hole CH1 may be formed on the source protective pattern 141, and may expose at least a portion of an upper surface of the source protective pattern 141. The drain contact hole CH2 may be formed on the drain protective pattern 142, and may expose at least a portion of an upper surface of the drain protective pattern 142.

In an embodiment, the width of the source protective pattern 141 and the width of the drain protective pattern 142 may be greater than a width of the source contact hole CH1 and a width of the drain contact hole CH2, respectively. Accordingly, a portion of the upper surface of the source protective pattern 141 may not be exposed by the source contact hole CH1, and may be covered by the insulation interlayer 170. Further, a portion of the upper surface of the drain protective pattern 142 may not be exposed by the drain contact hole CH2, and may be covered by the insulation interlayer 170.

The source electrode 181 and the drain electrode 182 may be disposed on the insulation interlayer 170 and may be electrically connected to the source region 131 and the drain region 132, respectively. The source electrode 181 may be in contact with the source protective pattern 141 through the source contact hole CH1 that is formed in the insulation interlayer 170, and the drain electrode 182 may be in contact with the drain protective pattern 142 through the drain contact hole CH2 that is formed in the insulation interlayer 170. The source electrode 181 and the drain electrode 182 may include at least one of copper (Cu), a cooper alloy, aluminum (Al), an aluminum alloy, molybdenum (Mo), and a molybdenum alloy.

The source protective pattern 141 may be disposed between the source region 131 of the active pattern 130 and the source electrode 181, and the drain protective pattern 142 may be disposed between the drain region 132 of the active pattern 130 and the drain electrode 182. Accordingly, the source electrode 181 and the drain electrode 182 may not be in direct contact with the source region 131 and the drain region 132, respectively. The source electrode 181 may be electrically connected to the source region 131 through the source protective pattern 141, and the drain electrode 182 may be electrically connected to the drain region 132 through the drain protective pattern 142.

Hereinafter, a method of manufacturing a transistor substrate according to an embodiment will be described with reference to FIGS. 1 to 10.

FIGS. 2, 3, 4, 5, 6, 7, 8, 9, and 10 are cross-sectional views illustrating a method of manufacturing the transistor substrate in FIG. 1.

Referring to FIG. 2, an oxide semiconductor layer including a first oxide semiconductor layer 130a and a second oxide semiconductor layer 140a may be formed on the substrate 110.

First, the buffer layer 120 may be formed on the substrate 110. For example, the buffer layer 120 may be formed of silicon oxide (SiOₓ), silicon nitride (SiNₓ), etc. by chemical vapor deposition (CVD), sputtering, etc.

Then, the first oxide semiconductor layer 130a containing tin (Sn) may be formed on the buffer layer 120, and the second oxide semiconductor layer 140a not containing tin (Sn) may be formed on the first oxide semiconductor layer 130a to form the oxide semiconductor layer. For example, the first oxide semiconductor layer 130a may be formed of tin oxide (SnO₂), zinc tin oxide (ZTO), indium zinc tin oxide (IZTO), indium gallium zinc tin oxide (IGZTO), etc. by chemical vapor deposition (CVD), sputtering, etc., and the second oxide semiconductor layer 140a may be formed of zinc oxide (ZnO), indium oxide (InO), gallium oxide (GaO), indium zinc oxide (IZO), indium gallium oxide (IGO), indium gallium zinc oxide (IGZO), etc. by chemical vapor deposition (CVD), sputtering, etc.

Then, a photoresist layer 310 may be formed on the oxide semiconductor layer. The photoresist layer 310 may be formed of a photosensitive organic material. In an embodiment, the photoresist layer 310 may include a positive photosensitive organic material of which a portion exposed to light may be removed. In another embodiment, the photoresist layer 310 may include a negative photosensitive organic material of which a portion exposed to light may be hardened.

Then, a halftone mask 400 may be disposed on or placed above the photoresist layer 310, and the photoresist layer 310 may be exposed to light by using the halftone mask 400. The halftone mask 400 may include a transmission portion 410, a shielding portion 420, and a transflective portion 430. The transmission portion 410 may transmit light, the shielding portion 420 may block light, and the transflective portion 430 may transmit a portion of light. In this case, a light transmittance of the transflective portion 430 may be less than a light transmittance of the transmission portion 410 and greater than a light transmittance of the shielding portion 420.

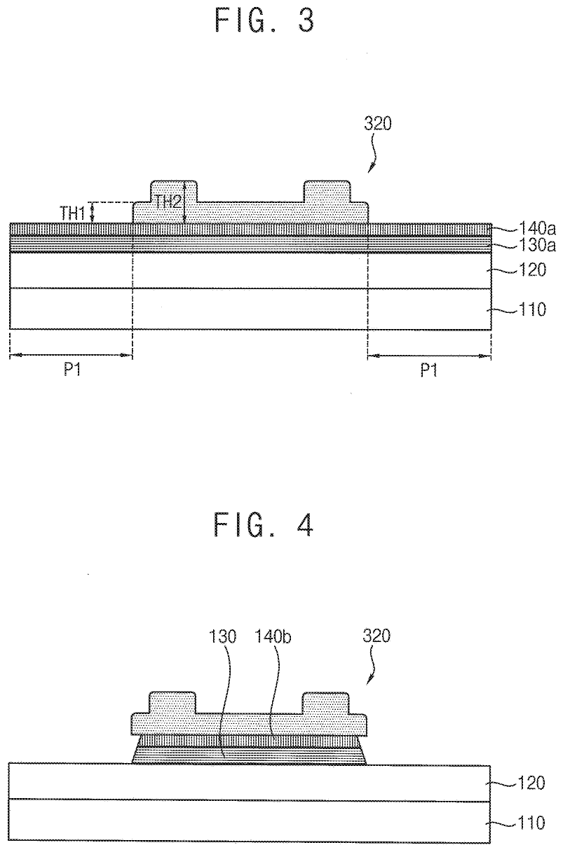

Referring to FIG. 3, a photoresist pattern 320 may be formed on the oxide semiconductor layer.

The photoresist layer 310 to which light is irradiated may be developed to form the photoresist pattern 320. A portion of the photoresist layer 310 corresponding to the transmission portion 410 may be substantially completely removed, and a portion of the photoresist layer 310 corresponding to the shielding portion 420 may not be substantially removed and may remain. A portion of the photoresist layer 310 corresponding to the transflective portion 430 may be partially removed. Accordingly, the photoresist pattern 320 has a first thickness TH1 corresponding to the transflective portion 430 of the halftone mask 400 and has a second thickness TH2 corresponding to the shielding portion 420 of the halftone mask 400. The second thickness TH2 may be greater than the first thickness TH1 due to the difference in an amount of light transmitted therethrough.

The photoresist pattern 320 may expose a first portion P1 of the oxide semiconductor layer. The first portion P1 of the oxide semiconductor layer may correspond to the transmission portion 410 of the halftone mask 400.

Referring to FIG. 4, the first portion P1 of the oxide semiconductor layer may be etched.

The first portion P1 of the oxide semiconductor layer may be etched by a wet etching using a first etchant. In an embodiment, the first etchant may include hydrogen fluorine (HF). In this case, the first etchant may etch the first oxide semiconductor layer 130a that contains tin (Sn) together with the second oxide semiconductor layer 140a that does not contain tin (Sn). After the wet etching, a remaining portion of the first oxide semiconductor layer 130a on the buffer layer 120 may correspond to the active pattern 130, and a remaining portion of the second oxide semiconductor layer 140a on the active pattern 130 may correspond to a second oxide semiconductor layer 140b.

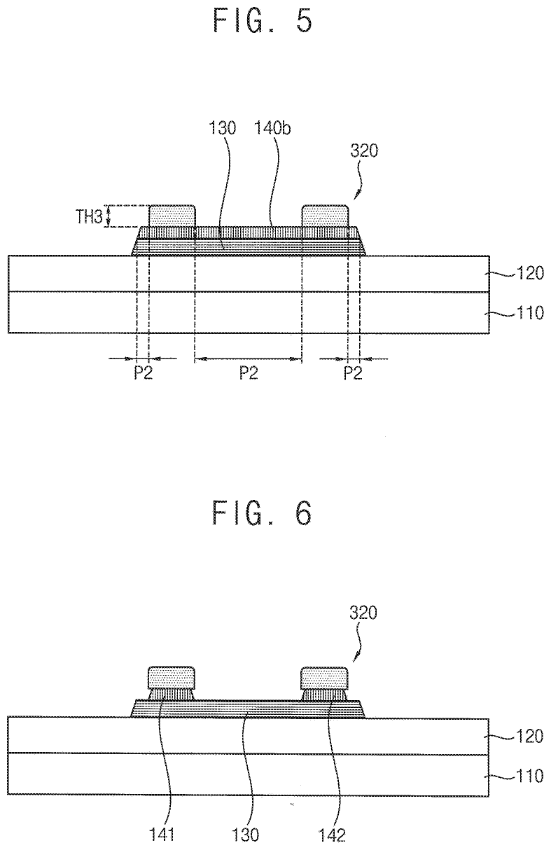

Referring to FIG. 5, the photoresist pattern 320 may be ashed.

According to one embodiment, the photoresist pattern 320 may be ashed by oxygen plasma using oxygen (O₂) gas. After ashing the photoresist pattern 320, a portion of the photoresist pattern 320 that has the first thickness TH1 may be substantially completely removed, and a portion of the photoresist pattern 320 that has the second thickness TH2 may be partially removed. Accordingly, a portion of the photoresist pattern 320 that corresponds to the shielding portion 420 of the halftone mask 400 has a third thickness TH3 that is less than the second thickness TH2.

The photoresist pattern 320 after being ashed may expose a second portion P2 of the second oxide semiconductor layer 140b. The second portion P2 of the second oxide semiconductor layer 140b may correspond to the transflective portion 430 of the halftone mask 400.

Referring to FIG. 6, the second portion P2 of the second oxide semiconductor layer 140b may be etched.

According to one embodiment, the second portion P2 of the second oxide semiconductor layer 140b may be etched by a wet etching using a second etchant that may be different from the first etchant. In an embodiment, the second etchant may include at least one of phosphoric acid (H₃PO₄), nitric acid (HNO₃), and acetic acid (CH₃COOH). In this case, the second etchant may etch the second oxide semiconductor layer 140b that does not tin (Sn), and may not etch the active pattern 130 that contains tin (Sn). The first etchant may etch the active pattern 130 that contains tin (Sn), however, the second etchant may not etch the active pattern 130 that contains tin (Sn). The source protective pattern 141 and the drain protective pattern 142 may be formed on the active pattern 130 after etching the second portion P2 of the second oxide semiconductor layer 140b. The source protective pattern 141 and the drain protective pattern 142 may be formed on opposite ends of the active pattern 130 as being spaced apart from each other.

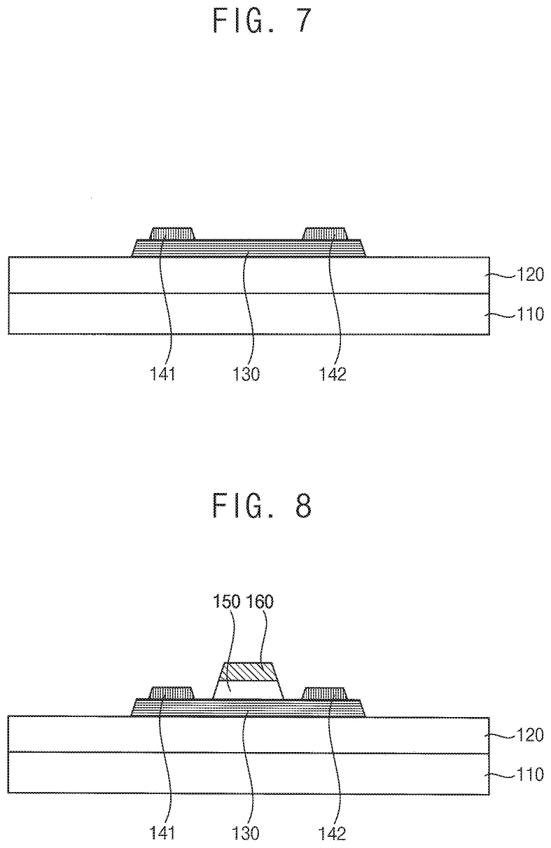

Referring to FIG. 7, the photoresist pattern 320 may be stripped. In one embodiment, the photoresist pattern 320 may be stripped by using sulfuric acid (H₂SO₄), hydrogen peroxide (H₂O₂), etc.

Referring to FIG. 8, the gate insulation layer 150 and the gate electrode 160 may be formed on the active pattern 130.

First, the gate insulation layer 150 may be formed on a center portion of the active pattern 130. The center portion of the active pattern 130 may be spaced apart from the opposite ends of the active pattern 130 on which the source protective pattern 141 and the drain protective pattern 142 are respectively formed. For example, an insulation layer that may be formed of silicon oxide (SiOₓ), silicon nitride (SiNₓ), etc. may cover the active pattern 130, the source protective pattern 141, and the drain protective pattern 142 by chemical vapor deposition (CVD), sputtering, etc. on the buffer layer 120, and the insulation layer may be patterned to overlap the center portion of the active pattern 130 thereby forming the gate insulation layer 150.

Then, the gate electrode 160 may be formed on the gate insulation layer 150. For example, a conductive layer may be formed of copper (Cu), aluminum (Al), molybdenum (Mo), etc. may cover the active pattern 130, the source protective pattern 141, the drain protective pattern 142, and the gate insulation layer 150 by chemical vapor deposition (CVD), sputtering, etc. on the buffer layer 120, and the conductive layer may be patterned to overlap the center portion of the active pattern 130 thereby forming the gate electrode 160 on the gate insulation layer 150. In one embodiment, the same pattern or different patterns may be used to form the gate insulation layer 150 and the gate electrode 160 in a patterning process of CVD or sputtering.

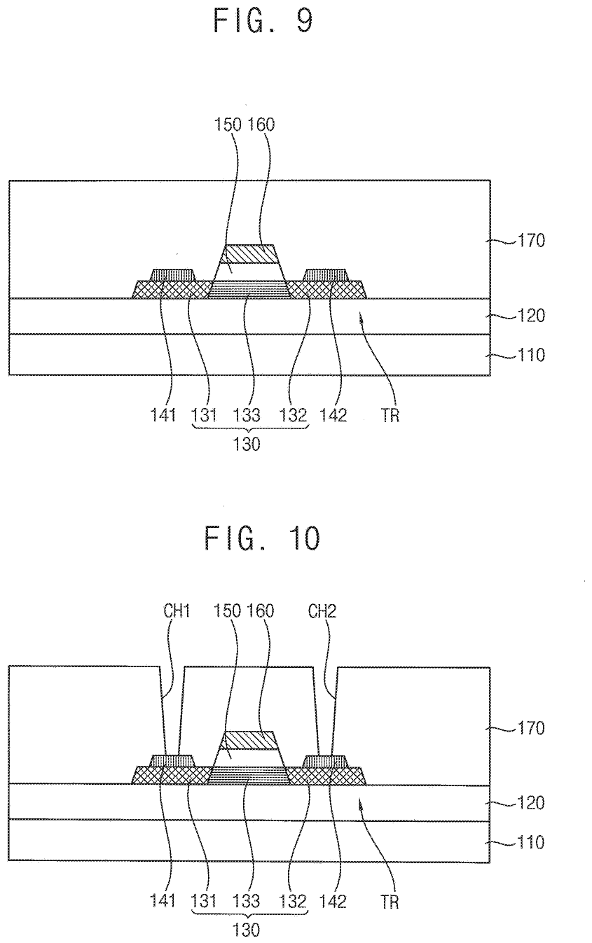

Referring to FIG. 9, the insulation interlayer 170 may be formed on the active pattern 130, the source protective pattern 141, the drain protective pattern 142, and the gate electrode 160. For example, the insulation interlayer 170 covering the active pattern 130, the source protective pattern 141, the drain protective pattern 142, and the gate electrode 160 may be formed of silicon oxide (SiOₓ), silicon nitride (SiNₓ), etc. by chemical vapor deposition (CVD), sputtering, etc. on the buffer layer 120.

The insulation interlayer 170 may be in direct contact with the opposite ends of the active pattern 130, the source protective pattern 141, and the drain protective pattern 142 because the gate insulation layer 150 does not cover the opposite ends of the active pattern 130, the source protective pattern 141, and the drain protective pattern 142. Therefore, the opposite ends of the active pattern 130, the source protective pattern 141, and the drain protective pattern 142 may be conductive because hydrogen inflowed from the insulation interlayer 170 may be diffused in the opposite ends of the active pattern 130, the source protective pattern 141, and the drain protective pattern 142. Accordingly, the source region 131 and the drain region 132 may be formed at the opposite ends of the active pattern 130, and the channel region 133 may be defined between the source region 131 and the drain region 132.

Referring to FIG. 10, the source contact hole CH1 and the drain contact hole CH2 that respectively expose at least a portion of an upper surface of the source protective pattern 141 and the drain protective pattern 142 may be formed in the insulation interlayer 170.

The source contact hole CH1 and the drain contact hole CH2 may be formed in the insulation interlayer 170 by a dry etching using an etching gas. In an embodiment, the etching gas may include fluorine (F). In this case, the etching gas may etch the insulation interlayer 170, and may not etch the source protective pattern 141 and the drain protective pattern 142 that do not contain tin (Sn).

If the etching gas including fluorine (F) comes in contact with the active pattern 130 that contains tin (Sn), the etching gas may etch and therefore damage the active pattern 130. However, in the method of manufacturing the transistor substrate according to the embodiment, the source protective pattern 141 and the drain protective pattern 142 may be formed on the active pattern 130, and the source contact hole CH1 and the drain contact hole CH2 respectively corresponding to the source protective pattern 141 and the drain protective pattern 142 block the etching gas from contacting the active pattern 130. Accordingly, a damage to the active pattern 130 by the etching gas may be prevented.

Referring to FIG. 1, the source electrode 181 and the drain electrode 182 may be formed on the insulation interlayer 170.

The source electrode 181 may be in contact with the source protective pattern 141 by filling the source contact hole CH1, and the drain electrode 182 may be in contact with the drain protective pattern 142 by filling the drain contact hole CH2. For example, a conductive layer filling the source contact hole CH1 and the drain contact hole CH2 may be formed of copper (Cu), aluminum (Al), molybdenum (Mo), etc. by chemical vapor deposition (CVD), sputtering, etc. on the insulation interlayer 170, and the conductive layer may be patterned to form the source electrode 181 and the drain electrode 182.

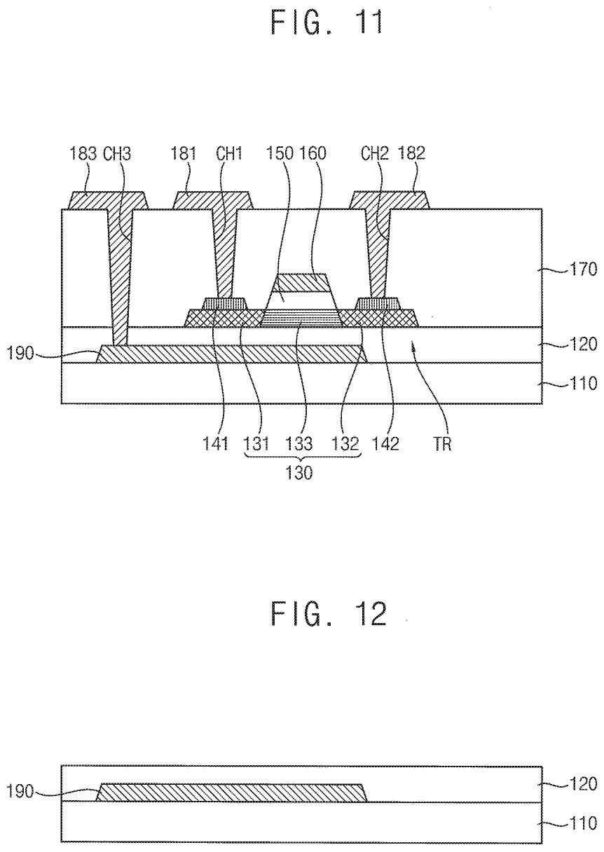

Hereinafter, a transistor substrate according to another embodiment will be described with reference to FIG. 11.

FIG. 11 is a cross-sectional view illustrating a transistor substrate according to another embodiment.

The transistor substrate according to the embodiment described with reference to FIG. 11 is substantially the same as the transistor substrate according to the embodiment described with reference to FIG. 1 except for an addition of a metal layer and a connection pattern.

Therefore, descriptions on elements of the transistor substrate shown in FIG. 11, which are substantially the same as or similar to those of the transistor substrate shown in FIG. 1, will be omitted.

Referring to FIG. 11, the transistor substrate may further include a metal layer 190.

The metal layer 190 may be disposed between the substrate 110 and the buffer layer 120. The buffer layer 120 may be disposed on the substrate 110 covering the metal layer 190. The metal layer 190 may overlap at least a portion of the active pattern 130. More specifically, the metal layer 190 may overlap at least a portion of the channel region 133. The metal layer 190 may include at least one or more of copper (Cu), a cooper alloy, aluminum (Al), an aluminum alloy, molybdenum (Mo), and a molybdenum alloy.

A metal layer contact hole CH3 may be formed in the buffer layer 120 and the insulation interlayer 170. The metal layer contact hole CH3 may be formed on the metal layer 190, and may expose at least a portion of an upper surface of the metal layer 190.

A connection pattern 183 that is connected to the metal layer 190 may be disposed on the insulation interlayer 170. The connection pattern 183 may be in contact with the metal layer 190 through the metal layer contact hole CH3 that is formed in the buffer layer 120 and the insulation interlayer 170. The connection pattern 183 may include at least one of copper (Cu), a cooper alloy, aluminum (Al), an aluminum alloy, molybdenum (Mo), and a molybdenum alloy. The connection pattern 183 may be disposed on substantially the same layer as the source electrode 181 and the drain electrode 182.

In an embodiment, the metal layer 190 may be electrically connected to the gate electrode 160 or the source electrode 181 through the connection pattern 183. In this case, a voltage of the gate electrode 160 or a voltage of the source electrode 181 may be applied to the metal layer 190.

The metal layer 190 may serve as a gate electrode of the transistor TR. In this case, the transistor TR may be a double gate type transistor having the metal layer 190 as a lower gate electrode and having the gate electrode 160 as an upper gate electrode.

According to one embodiment, one or more current paths may be formed at portions of the active pattern 130 that is adjacent to the gate electrode 160. In the transistor TR below which the metal layer 190 is disposed, an upper portion of the channel region 133 that is adjacent to the gate electrode 160 and a lower portion of the channel region 133 that is adjacent to the metal layer 190 may be used as current paths, therefore, a current path of the active pattern 130 may be expanded, and a charge mobility of the active pattern 130 may increase.

Hereinafter, a method of manufacturing a transistor substrate according to another embodiment will be described with reference to FIGS. 11 to 13.

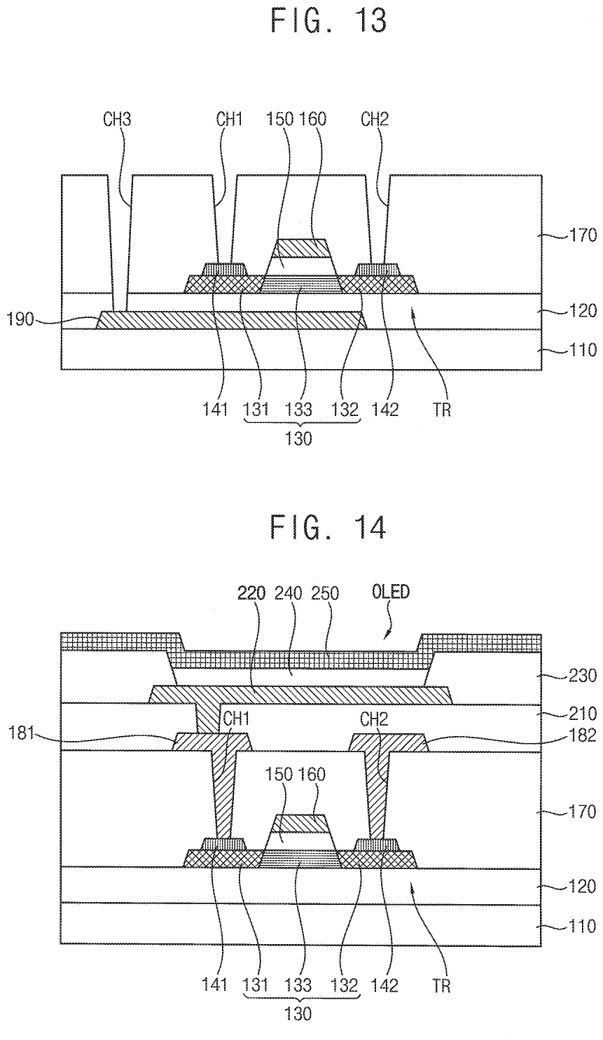

FIGS. 12 and 13 are cross-sectional views illustrating a method of manufacturing the transistor substrate in FIG. 11.

The method of manufacturing the transistor substrate according to the embodiment described with reference to FIGS. 11 to 13 is substantially the same as the method of manufacturing the transistor substrate according to the embodiment described with reference to FIGS. 1 to 10 except for an additional formation of the metal layer 190 and the connection pattern 183. Therefore, descriptions on elements of the method of manufacturing the transistor substrate shown in FIGS. 12 and 13, which are substantially the same as or similar to those of the method of manufacturing the transistor substrate shown in FIGS. 2, 3, 4, 5, 6, 7, 8, 9, and 10, will be omitted.

Referring to FIG. 12, the metal layer 190 may be formed on the substrate 110 before forming the active pattern 130.

First, the metal layer 190 may be formed on the substrate 110 before forming the buffer layer 120. For example, a conductive layer may be formed of copper (Cu), aluminum (Al), molybdenum (Mo), etc. by using chemical vapor deposition (CVD), sputtering, etc. on the substrate 110, and the conductive layer may be patterned to form the metal layer 190. Then, the buffer layer 120 covering the metal layer 190 may be formed on the substrate 110.

Referring to FIG. 13, the metal layer contact hole CH3 that exposes at least a portion of an upper surface of the metal layer 190 may be formed in the buffer layer 120 and the insulation interlayer 170.

According to one embodiment, the metal layer contact hole CH3 may be formed in the buffer layer 120 and the insulation interlayer 170 by a dry etching using an etching gas. In an embodiment, the etching gas may include fluorine (F). In this case, the etching gas may etch the buffer layer 120 and the insulation interlayer 170, and may not etch the metal layer 190.

In an embodiment, the metal contact hole CH3 may be substantially simultaneously formed with the source contact hole CH1 and the drain contact hole CH2. In this case, the source contact hole CH1, the drain contact hole CH2, and the metal contact hole CH3 may be substantially simultaneously formed by the etching gas including fluorine (F).

Without the source protective pattern 141 and the drain protective pattern 142, the etching gas including fluorine (F) may etch the active pattern 130 that contains tin (Sn) thereby damaging the active pattern 130 in a process of simultaneously forming the source contact hole CH1, the drain contact hole CH2, and the metal contact hole CH3 with the etching gas because a depth of the metal contact hole CH3 is greater than a depth of the source contact hole CH1 and a depth of the drain contact hole CH2. However, in the method of manufacturing the transistor substrate according to the present embodiment, the source protective pattern 141 and the drain protective pattern 142 may be formed on the active pattern 130, and the source contact hole CH1 and the drain contact hole CH2 that respectively correspond to the source protective pattern 141 and the drain protective pattern 142 may be formed such that the etching gas may not etch the active pattern 130.

Referring to FIG. 11, the connection pattern 183 may be formed on the insulation interlayer 170. The connection pattern 183 may be in contact with the metal layer 190 by filling the metal layer contact hole CH3.

In an embodiment, the connection pattern 183 may be substantially simultaneously formed as the source electrode 181 and the drain electrode 182. For example, a conductive layer filling the source contact hole CH1, the drain contact hole CH2, and the metal layer contact hole CH3 may be formed of copper (Cu), aluminum (Al), molybdenum (Mo), etc. by chemical vapor deposition (CVD), sputtering, etc. on the insulation interlayer 170, and the conductive layer may be patterned to substantially simultaneously form the source electrode 181, the drain electrode 182, and the connection pattern 183.

Hereinafter, a display device according to an embodiment will be described with reference to FIG. 14.

The display device according to the embodiment may include one of the transistor substrates according to the aforementioned embodiments.

FIG. 14 is a cross-sectional view illustrating a display device according to an embodiment.

Referring to FIG. 14, the display device may include the substrate 110, the transistor TR, and an organic light emitting diode OLED.

The display device according to the embodiment may include the transistor substrate illustrated in FIG. 1. However, in the present embodiment, the display device may include the transistor substrate illustrated in FIG. 11.

A passivation layer 210 covering the transistor TR may be disposed on the transistor TR. A first electrode 220 may be disposed on the passivation layer 210. The first electrode 220 may include a transparent conductive material such as indium tin oxide (ITO), indium zinc oxide (IZO), zinc oxide (ZnO), indium oxide (In₂O₃), etc. or a reflective metal such as lithium (Li), calcium (Ca), lithium fluoride/calcium (LiF/Ca), lithium fluoride/aluminum (LiF/Al), aluminum (Al), silver (Ag), magnesium (Mg), gold (Au), etc. The first electrode 220 may be connected to the source electrode 181 of the transistor TR, and may serve as an anode of the organic light emitting diode OLED.

A pixel defining layer 230 may be disposed on the passivation layer 210 and an edge of the first electrode 220. The pixel defining layer 230 may have an opening that overlaps the first electrode 220. The pixel defining layer 230 may include a polyacrylate-based or polyimide-based resin, a silica-based inorganic material, etc.

An emission layer 240 may be disposed in the opening of the pixel defining layer 230. The emission layer 240 may include an organic material. A second electrode 250 may be disposed on the pixel defining layer 230 and the emission layer 240. The second electrode 250 may include a transparent conductive material such as indium tin oxide (ITO), indium zinc oxide (IZO), zinc oxide (ZnO), indium oxide (In₂O₃), etc. or a reflective metal such as lithium (Li), calcium (Ca), lithium fluoride/calcium (LiF/Ca), lithium fluoride/aluminum (LiF/Al), aluminum (Al), silver (Ag), magnesium (Mg), gold (Au), etc. The second electrode 250 may serve as a cathode of the organic light emitting diode OLED. The first electrode 220, the emission layer 240, and the second electrode 250 may form the organic light emitting diode OLED.

The transistor substrate according to the embodiments may be applied to a display device included in various electronic devices such as a computer, a notebook, a mobile phone, a smartphone, a smart pad, a PMP, a PDA, an MP3 player, or the like.

Although the transistor substrates, the methods of manufacturing the transistor substrates, and the display devices according to the exemplary embodiments have been described with reference to the drawings, the illustrated embodiments are examples, and may be modified and changed by a person having ordinary knowledge in the relevant technical field without departing from the technical spirit described in the present disclosure.

What is claimed is:

1. A transistor substrate comprising:
a substrate;
an active pattern formed on the substrate, the active pattern including an oxide semiconductor that contains tin (Sn), and the active pattern comprising a source region, a drain region, and a channel region that is formed between the source region and the drain region;
a source protective pattern formed on the source region;
a drain protective pattern formed on the drain region;
a gate electrode overlapping at least a portion of the channel region;
an insulation interlayer covering the source protective pattern and the drain protective pattern;
a source electrode formed on the insulation interlayer, the source electrode being in contact with the source protective pattern through a source contact hole that is formed in the insulation interlayer; and
a drain electrode formed on the insulation interlayer, the drain electrode being in contact with the drain protective pattern through a drain contact hole that is formed in the insulation interlayer.

2. The transistor substrate of claim 1, wherein each of the source protective pattern and the drain protective pattern includes an oxide semiconductor that does not contain tin (Sn).

3. The transistor substrate of claim 1, wherein a width of the source protective pattern and a width of the drain protective pattern are greater than a width of the source contact hole and a width of the drain contact hole, respectively.

4. The transistor substrate of claim 1, wherein a width of the source protective pattern and a width of the drain protective pattern are less than a width of the source region and a width of the drain region, respectively.

5. The transistor substrate of claim 1, wherein the source electrode and the drain electrode are not in contact with the source region and the drain region, respectively.

6. The transistor substrate of claim 1, further comprising:
a gate insulation layer formed between the channel region and the gate electrode, the gate insulation layer overlapping at least a portion of the channel region.

7. The transistor substrate of claim 1, further comprising:
a buffer layer formed between the substrate and the active pattern; and
a metal layer formed between the substrate and the buffer layer, the metal layer overlapping at least a portion of the channel region.

8. The transistor substrate of claim 7, further comprising:
a connection pattern formed on the insulation interlayer, the connection pattern being in contact with the metal layer through a metal layer contact hole formed in the buffer layer and the insulation interlayer.

9. The transistor substrate of claim 8, wherein the metal layer is electrically connected to the gate electrode or the source electrode through the connection pattern.

10. A method of manufacturing a transistor substrate, the method comprising:
forming an active pattern on a substrate, the active pattern including an oxide semiconductor that contains tin (Sn);
forming a source protective pattern and a drain protective pattern on opposite ends of the active pattern;
forming a gate electrode on a center portion of the active pattern;
forming an insulation interlayer covering the source protective pattern and the drain protective pattern;
forming a source contract hole and a drain contact hole respectively exposing at least a portion of an upper surface of the source protective pattern and the drain protective pattern in the insulation interlayer; and
forming a source electrode and a drain electrode on the insulation interlayer by respectively filling the source contact hole and the drain contact hole.

11. The method of claim 10, wherein forming the active pattern, and forming the source protective pattern and the drain protective pattern comprise:
forming an oxide semiconductor layer on the substrate, the oxide semiconductor layer comprising a first oxide semiconductor layer that contains tin and a second oxide semiconductor layer that is formed on the first semiconductor layer and does not contain tin;
etching a first portion of the oxide semiconductor layer using a first etchant to form the active pattern; and
etching a second portion of the second oxide semiconductor layer using a second etchant to form the source protective pattern and the drain protective pattern.

12. The method of claim 11, wherein the first etchant includes hydrogen fluoride (HF).

13. The method of claim 11, wherein the second etchant includes at least one of phosphoric acid (H₃PO₄), nitric acid (HNO₃), and acetic acid (CH₃COOH).

14. The method of claim 11, wherein forming the active pattern, and forming the source protective pattern and the drain protective pattern further comprise:
forming a photoresist pattern exposing the first portion of the oxide semiconductor layer on the oxide semiconductor layer after forming the oxide semiconductor layer and before etching the first portion of the oxide semiconductor layer;
ashing the photoresist pattern to expose the second portion of the second oxide semiconductor layer after etching the first portion of the oxide semiconductor layer and before etching the second portion of the second oxide semiconductor layer; and
stripping the photoresist pattern after etching the second portion of the second oxide semiconductor layer.

15. The method of claim 14, wherein forming the active pattern, and forming the source protective pattern and the drain protective pattern further comprise:
after forming the oxide semiconductor layer and before forming the photoresist pattern,
forming a photoresist layer on the oxide semiconductor layer; and
exposing the photoresist layer using a halftone mask.

16. The method of claim 10, wherein the source contact hole and the drain contact hole are formed by an etching gas including fluorine (F).

17. The method of claim 10, further comprising:
forming a metal layer on the substrate and forming a buffer layer on the metal layer before forming the active pattern;
forming a metal layer contact hole exposing at least a portion of an upper surface of the metal layer in the buffer layer and the insulation interlayer; and
forming a connection pattern on the insulation interlayer by filling the metal layer contact hole.

18. The method of claim 17, wherein:
the metal layer contact hole is simultaneously formed with the source contact hole and the drain contact hole, and
the connection pattern is simultaneously formed with the source electrode and the drain electrode.

19. A display device comprising:
a substrate;
an active pattern formed on the substrate, the active pattern including an oxide semiconductor that contains tin (Sn), and the active pattern comprising a source region, a drain region, and a channel region that is formed between the source region and the drain region;
a source protective pattern formed on the source region;
a drain protective pattern formed on the drain region;
a gate electrode overlapping at least a portion of the channel region;
an insulation interlayer covering the source protective pattern and the drain protective pattern;
a source electrode formed on the insulation interlayer, the source electrode being in contact with the source protective pattern through a source contact hole that is formed in the insulation interlayer;
a drain electrode formed on the insulation interlayer, the drain electrode being in contact with the drain protective pattern through a drain contact hole that is formed in the insulation interlayer;
a first electrode electrically connected to the source electrode or the drain electrode;
a second electrode formed opposite to the first electrode; and
an emission layer formed between the first electrode and the second electrode.

20. The display device of claim 19, wherein each of the source protective pattern and the drain protective pattern includes an oxide semiconductor that does not contain tin.
